(19) United States
(12) Patent Application Publication
(10) Pub. No.: US 2023/0343805 A1
(43) Pub. Date: Oct. 26, 2023

(54) OPTOELECTRONIC SYSTEM AND PHOTODETECTOR FOR OPTOELECTRONIC SYSTEM

(71) Applicant: City University of Hong Kong, Kowloon (HK)

(72) Inventors: Xinge Yu, Kowloon (HK); Zhan Gao, Kowloon (HK)

(21) Appl. No.: 17/727,047

(22) Filed: Apr. 22, 2022

(51) Int. Cl. H01L 27/146; H01L 31/103; H01L 31/0352; H01L 31/02; H01L 27/142

(52) U.S. Cl. CPC H01L 27/14634; H01L 27/14625; H01L 27/14643; H01L 31/1032; H01L 31/035209; H01L 31/02005; H01L 27/14641; H01L 27/142

(57) ABSTRACT

A photodetector for an optoelectronic system and an optoelectronic system including the photodetector. The photodetector includes a flexible substrate, a plurality of photodetector units attached to the flexible substrate, and a circuit attached to the flexible substrate. Each of the plurality of photodetector units are arranged to sense optical radiation and generate a photocurrent signal based on the sensed optical radiation. The circuit comprises a plurality of conductors electrically connected with the plurality of photodetector units. The circuit is arranged to be connected with a signal processor arranged to process the photocurrent signals to generate an image associated with the sensed optical radiation.

### TECHNICAL FIELD

The invention relates to an optoelectronic system and a photodetector for an optoelectronic system. The optoelectronic system may be used as at least part of an imaging system.

### BACKGROUND

The eye is an important organ for human and animals, as it can detect optical radiation (e.g., visible light) of the environment in which the human or animal is in, to assist the human or animal in navigating the environment. The structure and function of the eyes of different animals may be different. For example, mammal eyes can typically provide focal length tunability, high-resolution imaging with low aberration, and light intensity modulation, whereas compound eyes can typically provide wide field of view and high motion sensitivity.

Inspired by these different types of eyes in nature, which have different structure, function, and advantage(s), various research efforts have been devoted to develop bio-inspired electronic eye or like imaging device that can mimic natural eyes.

### SUMMARY

In a first aspect of the invention, there is provided a photodetector for an optoelectronic system, comprising: a flexible substrate; a plurality of photodetector units attached to the flexible substrate, and a circuit attached to the flexible substrate. Each of the plurality of photodetector units is arranged to sense optical radiation and generate a photocurrent signal based on the sensed optical radiation. The circuit comprises a plurality of conductors electrically connected with the plurality of photodetector units. The circuit is arranged for connecting with a signal processor that is arranged to process the photocurrent signals, e.g., to generate an image associated with the sensed optical radiation. The photodetector is relatively soft and flexible, e.g., such that it can be bent. The signal processor may be a semiconductor device parameter analyzer.

The optical radiation includes one or more or all of: ultraviolet (UV) radiation, visible light (Vis) radiation, and infrared (IR) radiation. The photocurrent signal (e.g., current value) may vary based on an intensity of the sensed optical radiation.

The plurality of photodetector units may be arranged on or embedded in the flexible substrate. The plurality of photodetector units may be arranged in an array having one or more rows and one or more columns. The number of rows and the number of columns may be the same or different. In one example, there are 256 photodetector units arranged in a 16×16 array. The plurality of photodetector units may be of the same size or may be of at least two different sizes. The plurality of photodetector units may be spaced apart evenly or unevenly. An area or footprint of each of the plurality of photodetector units may be within 1 cm². When the photodetector is bent, the array may deform accordingly.

Optionally, each of the plurality of photodetector units comprises a ZnO—MoS2 material. Optionally, each of the plurality of photodetector units comprises a ZnO—MoS2 film, e.g., thin film. Optionally, the ZnO—MoS2 film comprises ZnO nanoparticles and MoS2 monolayer composite. The ZnO particles may be arranged in a layer. Optionally, the ZnO nanoparticles and MoS2 monolayer composite is formed by spray coating of ZnO nanoparticles-MoS2 solution. Optionally, the ZnO nanoparticles-MoS2 solution contains 2-6 wt. %, 3-5 wt. %, about 3 wt. %, about 4 wt. %, or about 5 wt. % of ZnO nanoparticles.

Optionally, the flexible substrate is in the form of a film, e.g., thin film. Optionally, the flexible substrate is optically-transparent to the optical radiation. The flexible substrate may be transparent or translucent. Optionally, the substrate is made at least partly or substantially entirely of polyvinyl alcohol (PVA), e.g., in the form of a film or thin film. Additionally or alternatively the substrate can be made with other materials.

Optionally, the circuit is optically-transparent to the optical radiation. The circuit may be transparent or translucent. Optionally, the circuit may be arranged on or embedded in the flexible substrate. Optionally, the plurality of conductors comprises wires providing multiple connection paths. The wires may be nanowires. In one example, the plurality of wires or nanowires are made of silver. In another example, the wires or nanowires can be made of other metal(s). Optionally, the circuit comprises a plurality of circuit portions, each having respective patterned wires, and the plurality of circuit portions are angularly spaced apart. In one example, the plurality of circuit portions comprise 4 portions spaced apart by 90 degrees. Optionally, each of the circuit portion includes a relatively narrow inner portion, a relatively wide outer portion, and a middle tapering portion connected between the relatively narrow inner portion and the relatively wide outer portion.

Optionally, the photodetector is optically-transparent to the optical radiation. In some examples, the photodetector includes at least 70% or at least 80% optical transmittance for optical radiation in the wavelength range of 350-1000 nm. In one example, the photodetector includes at least 85% optical transmittance for optical radiation in the wavelength range of 450-900 nm. This facilitates dual-sided imaging.

Optionally the photodetector may be used as or in an artificial retina.

In a second aspect, there is provided a method for making the photodetector of the first aspect. The method includes: attaching a circuit to a flexible substrate; and attaching a plurality of photodetector units to the flexible substrate.

Optionally, attaching the circuit comprises: applying a conductive solution onto a substrate to form a plurality of conductors on the substrate; and drop-casting a flexible substrate material solution on the substrate so as to form a flexible substrate attached with the plurality of conductors.

Optionally, the method further comprises: removing, from the substrate, the flexible substrate attached with the plurality of conductors.

Optionally, applying a conductive solution comprises: spray coating the conductive solution on the substrate to form the plurality of conductors.

Optionally, the method further comprises: masking (e.g., using a patterned photoresistive mask) part of the substrate prior to spray coating the conductive solution on the substrate.

Optionally, the method further comprises: masking (e.g., using a patterned photoresistive mask) the plurality of conductors formed on the substrate; and performing a photolithography operation on the masked conductor layer so as to remove some of the conductors.

Optionally, the conductive solution comprises silver nanowire solution and the conductor layer comprises a silver nanowire layer.

Optionally, the substrate comprises a glass substrate.

Optionally, attaching the circuit further comprises: cleaning the substrate prior to applying the conductive solution to the substrate.

Optionally, attaching the plurality of photodetector units comprises: masking (e.g., using a patterned photoresistive mask) part of the flexible substrate attached with the plurality of conductors; and spray coating a ZnO—MoS₂ solution onto the masked flexible substrate to attach a plurality of ZnO—MoS₂ photodetector units to the flexible substrate attached with the plurality of conductors.

Optionally, the ZnO—MoS₂ solution comprises 3-6 wt. % of ZnO nanoparticles.

Optionally, the method further comprises heating the spray coated ZnO—MoS₂ solution to form the plurality of ZnO—MoS₂ photodetector units.

Optionally, the ZnO—MoS₂ photodetector units are electrically connected with the plurality of conductors when formed.

In a third aspect, there is provided a system including the photodetector of the first aspect or the photodetector produced using the method of the second aspect. The system may be an imaging system, an optoelectronic system, etc.

In a fourth aspect, there is provided an optoelectronic system, comprising: a support structure having a projection or recess that provides a curved surface, a photodetector, and a control circuit. The photodetector is the photodetector of the first aspect. At least the plurality of photodetector units attached (e.g., directly) to the curved surface. The control circuit is electrically connected with the circuit of the photodetector, for connecting the photodetector with a signal processor. The signal processor being arranged to process the photocurrent signals, e.g., to generate an image associated with the sensed optical radiation.

Optionally, the projection or recess is generally dome-shaped. Optionally, the generally dome-shape is generally hemispherical. The curved surface may be a convex surface or a concave surface. Optionally, the curved surface is optically-transparent.

Optionally, the plurality of photodetector units are attached generally centrally of the curved surface.

Optionally, the support structure is made of polymethyl methacrylate (PMMA).

Optionally, the control circuit is arranged at least partly on a circuit board (e.g., PCB), the circuit board comprises an optically-transparent portion (e.g., a through-hole) at a location corresponding to the curved surface.

Optionally, at least part of the photodetector, e.g., at least part of the circuit, is sandwiched between the circuit board and the support structure.

Optionally, the circuit board and the support structure are fixed to each other. For example, the circuit board and the support structure are fastened together with fasteners (e.g., screws, bolts, etc.). The fastening tightness of the circuit board and the support structure may be adjustable.

Optionally, the optoelectronic system further comprises anchor pads arranged between the circuit board and the support structure for anchoring the photodetector. Optionally, the anchor pads are made of silicone polydimethylsiloxane (PDMS).

Optionally, the control circuit comprises: one or more multiplexers connected with the plurality of photodetector units, each of the one or more multiplexers providing a plurality of channels each having at least one switch and at least one of the plurality of photodetector units; and a controller operably connected with the one or more multiplexers for controlling operation of the switches of the one or more multiplexers. In one example the control circuit includes multiple multiplexers. Each of the channel in a multiplexer may include only one switch and only one photodetector unit. Optionally, the controller is provided by an Arduino Nano.

Optionally, the controller is arranged to selectively open and close the switch to selectively disconnect and connect the respective photodetector unit with the signal processor. Optionally, the controller is arranged to sequentially close the switches so as to sequentially connect each one of the plurality of photodetector units to the signal processor. In this control, only one photodetector unit is connected to the signal processor at a time, i.e., when one of the photodetector unit is connected to the signal processor the other photodetector units are disconnected. The controller may be arranged to sequentially close all of the switches once within seconds, e.g., 1 second. The controller may be arranged to repeat the process automatically.

Optionally, the optoelectronic system further comprises the signal processor connected with the control circuit. The signal processor may be a semiconductor device parameter analyzer. The signal processor may be electrically connected with the plurality of channels to collect the photocurrent signals generated by the plurality of photodetector units. The signal processor may be arranged to perform image reconstruction based on the photocurrent signals generated by the plurality of photodetector units. The signal processor may be arranged to perform image reconstruction by: converting the photocurrent signals to greyscale values; and generating an image based on the greyscale values. The signal processor may be further arranged to perform an interpolation operation to the greyscale values to generate the image. In the embodiment photocurrent signals may be continuously and sequentially obtained, and the signal processor may be arranged to generate a series of images that form a video stream.

Optionally, the optoelectronic system further comprises an energy source for powering operation of the optoelectronic system. In one example the energy source comprises a battery. In another example the energy source comprises a photovoltaic cell electrically connected with the photodetector. In this example, the plurality of photodetector units may be arranged in front of the photovoltaic cell.

Optionally, the optoelectronic system further comprises a lens arranged to focus optical radiation onto the plurality of photodetector units. The lens may be concave or convex.

Optionally, the optoelectronic system is arranged or incorporated in a portable device.

Optionally, the optoelectronic system is arranged to operate as an electronic eye.

In a fifth aspect, there is provided a visual prosthesis comprising: the photodetector of the first aspect, the photodetector made using the method of the second aspect, or the optoelectronic system of the fourth aspect.

Other features and aspects of the invention will become apparent by consideration of the detailed description and accompanying drawings. Any feature(s) described herein in relation to one aspect or embodiment may be combined with any other feature(s) described herein in relation to any other aspect or embodiment as appropriate and applicable.

Terms of degree such that “generally”, “about”, “substantially”, or the like, are, depending on context, used to take into account manufacture tolerance, degradation, trend, tendency, practical applications, etc.

### BRIEF DESCRIPTION OF THE DRAWINGS

Embodiments of the invention will now be described, by way of example, with reference to the accompanying drawings in which:

FIG. 1 is a schematic exploded view of a photodetector in one embodiment of the invention, with an inset showing it applied to an eye model;

FIG. 2 is a picture of an optoelectronic system in one embodiment of the invention;

FIG. 3 is a schematic diagram of a ZnO nanoparticles-MoS₂ monolayer composites in one embodiment of the invention;

FIG. 4 is an optical image of a photodetector mounted on a dome-shaped projection in one embodiment of the invention;

FIG. 5 is a flow diagram illustrating a method for making a photodetector in one embodiment of the invention;

FIG. 6A is a picture of a flexible circuit based on silver nanowires in one embodiment of the invention;

FIG. 6B is a picture illustrating the silver nanowire pads of the flexible circuit of FIG. 6A aligned with the pads of a PCB in one embodiment of the invention;

FIG. 7 is a picture of a photodetector attached to a window in one embodiment of the invention;

FIG. 8 is a graph showing optical transmittance of different materials of the photodetector in one embodiment of the invention;

FIG. 9 is a partial top view of the optoelectronic system of FIG. 2;

FIG. 10 is an enlarged SEM images of the photodetector of the optoelectronic system of FIG. 2;

FIG. 11 is a TEM image of a ZnO—MoS2 composite in one embodiment of the invention

FIG. 12A is a diagram illustrating the diffraction pattern of one part of the ZnO—MoS2 composite of FIG. 11;

FIG. 12B is a diagram illustrating the diffraction pattern of another part of the ZnO—MoS2 composite of FIG. 11;

FIG. 13 is a HRTEM image of a ZnO—MoS2 composite in one embodiment of the invention;

FIG. 14A is an HAADF-STEM image of a ZnO—MoS2 composite in one embodiment of the invention;

FIG. 14B is an HAADF-STEM image illustrating Molybdenum (Mo) in the ZnO—MoS2 composite;

FIG. 14C is an HAADF-STEM image illustrating Sulfur (S) in the ZnO—MoS2 composite;

FIG. 14D is an HAADF-STEM image illustrating Zinc (Zn) in the ZnO—MoS2 composite;

FIG. 14E is an HAADF-STEM image illustrating Oxygen (O) in the ZnO—MoS2 composite;

FIG. 15A is a graph illustrating Raman spectrum of MoS2 nanosheets, ZnO nanoparticles, and ZnO—MoS2 composites in one embodiment of the invention;

FIG. 15B is a graph illustrating XRD results of ZnO nanoparticles and ZnO—MoS2 composites in one embodiment of the invention;

FIG. 16A is an AFM image of exfoliated MoS2 nanosheets in one embodiment of the invention;

FIG. 16B is a graph showing thickness distribution of the exfoliated MoS2 nanosheets;

FIG. 16C is a TEM image of exfoliated MoS2 nanosheets in one embodiment of the invention;

FIG. 17A is a graph showing Mo3d spectrum of exfoliated MoS₂ nanosheets;

FIG. 17B is a graph showing S2p spectrum of exfoliated MoS2 nanosheets;

FIG. 18 is a schematic diagram of a photodetector unit based on ZnO NPs-MoS2 monolayer composite in one embodiment of the invention;

FIG. 19 is an SEM image showing sectional view of the photodetector unit;

FIG. 20 is an SEM image showing another sectional view of the photodetector unit;

FIG. 21A is an SEM image showing sectional view of a ZnO film formed with 3 wt. % ZnO nanoparticles;

FIG. 21B is an SEM image showing sectional view of a ZnO film formed with 4 wt. % ZnO nanoparticles;

FIG. 21C is an SEM image showing sectional view of a ZnO film formed with 5 wt. % ZnO nanoparticles;

FIG. 21D is an SEM image showing sectional view of a ZnO film formed with 6 wt. % ZnO nanoparticles;

FIG. 22 is a graph showing current-voltage characteristics of the photodetector (under 1 mw/cm² illumination) with different concentration of ZnO nanoparticles;

FIG. 23 is a graph showing photo responsivity of the photodetector (under 1 mw/cm² illumination) with different concentration of ZnO nanoparticles;

FIG. 24 is a graph showing dark current-voltage characteristics of the photodetector (under 1 mw/cm² illumination) with different concentration of ZnO nanoparticles;

FIG. 25 is a graph showing current on/off ratio-voltage characteristics of the photodetector (under 1 mw/cm² illumination) with different concentration of ZnO nanoparticles;

FIG. 26 is a graph showing Responsivity and detectivity of the photodetector under 1 mw/cm² illumination;

FIG. 27 is a graph showing current-voltage characteristics of the photodetector under different light intensities;

FIG. 28 is a graph showing photocurrent of the photodetector with 4 wt. % ZnO nanoparticles under different light intensities;

FIG. 29A is a graph showing photocurrent-voltage characteristics of the photodetector units under bending condition;

FIG. 29B is a graph showing photocurrent variation of the photodetector units under different bending conditions;

FIG. 30A is a graph showing dynamic photo response measurements of the photodetector under 1 mw/cm²;

FIG. 30B is an enlarged view of the measurements of FIG. 30A;

FIG. 31 is a graph showing the TRPL decay spectra of MoS₂—ZnO and ZnO sample (with a 365 nm laser as excitation source);

FIG. 32 is a graph showing the photoluminescence (PL) spectrum of MoS₂—ZnO film and ZnO film (λ_{exc}=365 nm);

FIG. 33A is a graph showing UV-visual absorption spectra of ZnO;

FIG. 33B is a graph showing Kubelka-Munk transformed reflectance spectra of ZnO;

FIG. 33C is a graph showing UPS spectrum of ZnO;

FIG. 33D is a graph showing UV-visual absorption spectra of MoS2;

FIG. 33E is a graph showing Kubelka-Munk transformed reflectance spectra of MoS2;

FIG. 33F is a graph showing UPS spectrum of MoS2;

FIG. 34 is a schematic diagram illustrating the photodetector mechanism of MoS2-ZnO composite under UV light;

FIG. 35 is a schematic band diagrams of MoS2 and ZnO;

FIG. 36A is a side view of a support structure in one embodiment of the invention;

FIG. 36B is a top view of the support structure of FIG. 36A;

FIG. 37 is a picture showing layout of a PCB in an optoelectronic device in one embodiment of the invention;

FIG. 38 is a schematic circuit diagram illustrating a control circuit of an optoelectronic device in one embodiment of the invention;

FIG. 39A is a graph showing current signals obtained from the photodetector under the control of the controller in one embodiment of the invention;

FIG. 39B is a graph showing a portion of the signals in FIG. 39A;

FIG. 39C is a graph showing another portion of the signals in FIG. 39A;

FIG. 40 is a schematic diagram illustrating a photodetector perceiving UV light from opposite directions in one embodiment of the invention;

FIG. 41A is a picture showing a setup incorporate the photodetector for image acquisition in one embodiment of the invention;

FIG. 41B is a picture showing a pattern of a cross arranged on the lens in the setup of FIG. 41A;

FIG. 42 is a table illustrating properties of lens used in the experiments with the setup of FIG. 41A;

FIG. 43 is a diagram illustrating ray-tracing simulation of the lens set-up in the setup of FIG. 41A, with an inset showing matching of curvature of photodetector array with the focal plane;

FIG. 44A is a diagram illustrating a reconstructed image based on signals sensed by the photodetector units;

FIG. 44B is a diagram illustrating a reconstructed image based on signals sensed by the photodetector units;

FIG. 44C is a diagram illustrating a reconstructed image based on signals sensed by the photodetector units;

FIG. 45 is a schematic circuit diagram illustrating an application of a photodetector to a solar cell in one embodiment of the invention;

FIG. 46 is a schematic diagram of a setup for the application in FIG. 45;

and

FIG. 47 is a graph showing photo-voltage of the solar cell in FIG. 45 with and without photodetector.

### DETAILED DESCRIPTION

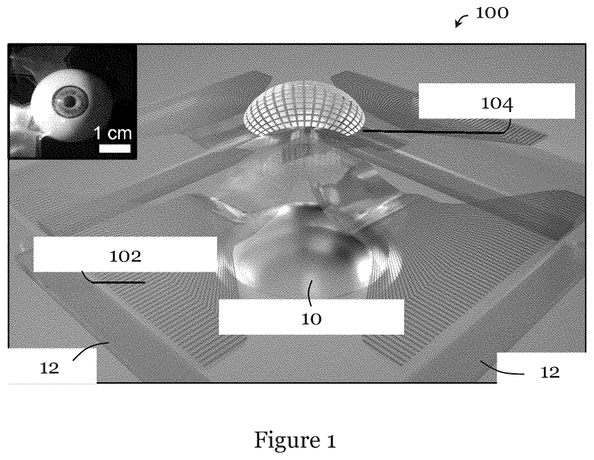

FIG. 1 shows a photodetector 100, in exploded view, in one embodiment of the invention. The photodetector 100 includes a flexible substrate, a circuit 102 arranged on the flexible substrate, and a photodetector unit array 104 having multiple photodetector units arranged in multiple rows and columns.

The photodetector units in the array 104 are attached to the flexible substrate (although the array 104 is shown as spaced apart from the substrate in this exploded view). Each of the photodetector unit in the array 104 is arranged to sense optical radiation (one or more of: ultraviolet (UV) radiation, visible light (Vis) radiation and infrared (IR) radiation) and generate a photocurrent signal based on the sensed optical radiation (e.g., its intensity). The photodetector units may be made of any material(s) that can generate a photocurrent signal based on sensed optical radiation. In this embodiment, the photodetector units comprises a ZnO—MoS2 material, in the form of a film or thin film. The ZnO—MoS2 film may include ZnO nanoparticles and MoS2 monolayer composite, e.g., formed by spray coating of ZnO nanoparticles-MoS₂ solution which contains, e.g., 2-6 wt. %, 3-5 wt. %, about 3 wt. %, about 4 wt. %, or about 5 wt. % of ZnO nanoparticles. The photodetector units may be optically-transparent to the optical radiation.

The circuit 102 comprises conductors electrically connected with the photodetector units in the array 104. In this embodiment, the conductors are wires, in particular nanowires, providing multiple connection paths. In this embodiment, the conductors are made of silver. However, in some other embodiments, the conductors can be made of other electrically-conductive or metallic materials. The circuit 102 is arranged for connecting with a signal processor (not shown) that is arranged to process the photocurrent signals generated by the photodetector units in the array 104, e.g., to generate an image associated with the sensed optical radiation. The circuit 102 may be optically-transparent to the optical radiation. In this embodiment, the circuit 102 has a generally cross-shaped in plan view, and it includes a central circuit portion and four circuit portions each having respective patterned silver nanowires. The four circuit portions are angularly spaced apart by approximately 90 degrees. Each of the circuit portion has a relatively narrow radially inner portion, a relatively wide radially outer portion, and a middle tapering portion connected between the relatively narrow radially inner portion and the relatively wide radially outer portion. For each of the circuit portion, the silver nanowires in the middle tapering portion diverge towards the relatively wide outer portion, and the silver nanowires in the relatively wide outer portion are generally parallel. The silver nanowires in the relatively wide outer portion are wider than the silver nanowires in the other two portion, and they can function as connection pads, e.g., for connecting with conductors on a circuit board.

In this embodiment the flexible substrate is in the form of a film or thin film, and it may be optically-transparent to the optical radiation. The flexible substrate may be made of soft plastic materials, such as polyvinyl alcohol (PVA) in this embodiment. The flexible substrate is substantially transparent hence is not clearly shown in FIG. 1.

In this embodiment, the photodetector 100 is optically-transparent to the optical radiation. The photodetector 100 may have at least 70% optical transmittance for optical radiation in the wavelength range of 350-1000 nm, and/or at least 85% optical transmittance for optical radiation in the wavelength range of 450-900 nm. In this embodiment, the photodetector 100 is relatively soft and flexible hence is bendable without substantially compromising its function. The photodetector may be used as or in an artificial retina or as part of an electronic eye system.

As shown in FIG. 1, the photodetector 100 is arranged on a support structure having a dome-shaped projection 10 that provides a curved surface, with the photodetector unit array 104 arranged on the curved surface and the conductors extending outwardly following the contour of the projection 10. In other embodiments, the projection may instead be a recess. The array 104 may be positioned centrally of the curved surface. The support structure may be made of polymethyl methacrylate (PMMA), which is optically-transparent to the optical radiation. Alternatively the support structure can made of other materials, which may be optically-transparent to the optical radiation. Anchor pads 12 are provided at the outer end of the circuit 102 to anchor the circuit 102. The anchor pads 12 in this example are made of polydimethylsiloxane (PDMS).

The inset image in FIG. 1 shows the photodetector 100 attached onto an eye model, with the array 104 aligned to the iris or pupil, and the circuit extending outwardly following the contour of the eyeball.

FIG. 2 shows an optoelectronic system 200 in one embodiment of the invention. The optoelectronic system 200 adopts a relatively simple structure. The optoelectronic system 200 includes a substrate 202 including a dome-shaped (e.g., generally hemispherical) projection that provides a curved surface, a photodetector 204 mounted onto the substrate 202, a control circuit. In this embodiment, the substrate 202 is made of PMMA. In some other embodiments, the substrate 202 may be made of other material(s). In this example, the photodetector 204 has the same general configuration as the photodetector 100 of FIG. 1, and in some embodiments the photodetector 204 may be the photodetector 100. The photodetector 204 includes a flexible substrate (e.g., PVA), 16×16 (=256) photodetector units arranged in an array, and the silver nanowires attached to the substrate of the photodetector and function as soft electrodes and interconnects. In this embodiment, the control circuit is arranged on a customized printed circuit board (PCB) 206. The PCB 206 is mounted to the substrate 202, or vice versa, e.g., using fasteners, such that the photodetector 204 is arranged between the substrate 202 and the PCB 206. The PCB 206 includes a through-hole that is aligned with the projection on the substrate 202 to allow the projection on the substrate 202 to extend through at least part of it. The control circuit of the PCB 206 electrically connects with the circuit of the photodetector 204 for connecting the photodetector 204 with a signal processor that processes the photocurrent signals generated by the photodetector units, e.g., to generate an image associated with the sensed optical radiation. The arrangement of the photodetector 204 on the substrate 202 follows that as described with reference to FIG. 1. Anchor pads, such as PDMS anchor pads, arranged to anchor the circuit of the photodetector 204 may be arranged between the substrate 202 and the PCB 206.

In one embodiment, the control circuit of the optoelectronic system 200 comprises multiplexer(s) connected with the photodetector units. The or each multiplexer may provide multiple channels each having at least one (e.g., one) switch and at least one (e.g., one) photodetector unit. The control circuit of the optoelectronic system 200 may further include a controller (e.g., provided by an Arduino Nano) operably connected with the multiplexer(s) for controlling operation of the switches of the multiplexer(s). The controller may be arranged to selectively open and close the switch to selectively disconnect and connect the respective photodetector unit with the signal processor (connected with the control circuit or PCB 206). In one operation example, the controller is arranged to sequentially close the switches of the multiplexer(s) so as to sequentially connect each one of the photodetector units to the signal processor. With this control, only one photodetector unit is connected to the signal processor at a time, i.e., when one of the photodetector unit is connected to the signal processor the other photodetector units are disconnected. The controller may be arranged to sequentially close all of the switches once within one or several seconds, and it may automatically repeat the process. The signal processor may be electrically connected with the channels of the multiplexer(s) to collect the photocurrent signals generated by the photodetector units. The signal processor reconstruct an image based on the photocurrent signals generated by the photodetector units. Each image frame may correspond to one cycle of sequentially closing of all of the switches by the controller to obtain the photocurrent signals. The signal processor may perform image reconstruction by: converting the photocurrent signals to greyscale values; and generating an image based on the greyscale values, optionally with an interpolation operation to the greyscale values.

The optoelectronic system 200 may further include an energy source for powering operation of the optoelectronic system. The energy source may be AC or DC power source (e.g., battery). In one example, the energy source comprises a photovoltaic cell electrically connected with the photodetector. The photodetector, or the photodetector units, may be aligned or arranged in front of the photovoltaic cell.

The optoelectronic system 200 may further include one or more lens (e.g., concave lens, convex lens, etc.) arranged to focus optical radiation onto the photodetector units.

The optoelectronic system 200 may be arranged in or incorporated in a portable device. In one example, the optoelectronic system 200 is arranged to function as an electronic eye.

The system 200 closely mimics the natural human eye: the incoming optical radiation (e.g., visible light beams) can be focused on the photodetector array (which corresponds to the retina) by the hemispherical projection (which corresponds to the eyeball) to generate photocurrent signals (which correspond to optic nerve signals) to the control circuit and signal processor (which corresponds to the brain).

As illustrated in FIG. 2, the PMMA hemispherical dome (in this example, 15 mm radius) imitate the shell of an eyeball, while the photodetector array on a soft and transparent PVA substrate can directly attach onto it to mimic the retina.

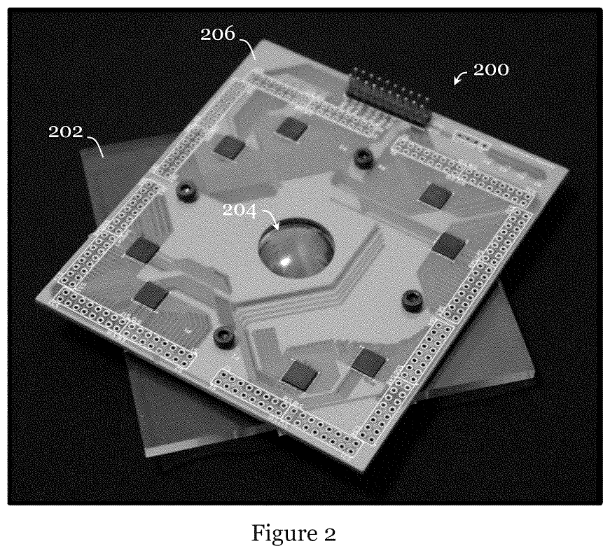

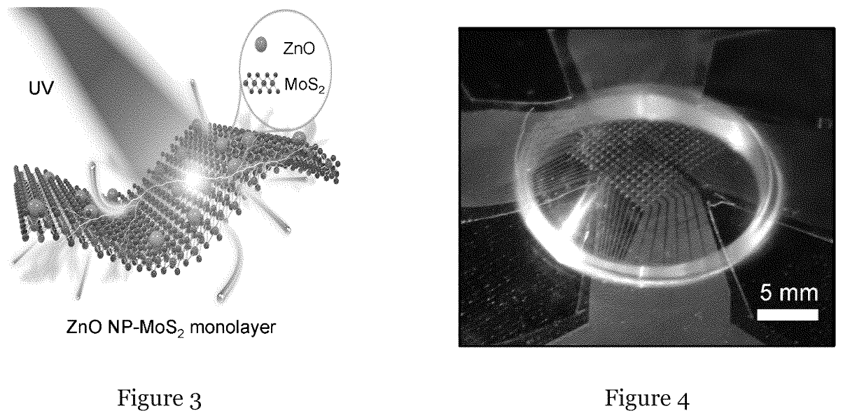

FIG. 3 shows a ZnO nanoparticles-MoS₂ monolayer composite-based photodetector unit for UV light optoelectronic response in one embodiment of the invention. The ZnO nanoparticles can be processed into a thin film by spray-coating at room temperature and maintain its UV-response under mechanical deformation. With the combination of the ZnO nanoparticles and the inherently soft MoS₂ monolayer, photo-generated charge carriers can be quickly separated by the built-in electrical field of the P-N junctions between ZnO—MoS₂, thus improving optoelectronic behaviors of the photodetector or the optoelectronic device.

FIG. 4 shows the photodetector 100 of FIG. 1 in assembled form and mounted on a projection of a support structure (substrate). As shown in FIG. 4, the soft photodetector array and the silver nanowires circuit smoothly interface with the hemispherical PMMA projection without wrinkling. Spray-coating of silver nanowires and transfer printing technologies enable silver nanowires embedded in the PVA substrate to form smooth, robust, and optically-transparent electrical circuits.

The photodetector 100 can be made using various methods. One embodiment of the method includes attaching a circuit to a flexible substrate; and attaching a photodetector units to the flexible substrate.

Attaching the circuit may include: applying (e.g., spray coating) a conductive solution onto a substrate (e.g., glass substrate) to form a plurality of conductors on the substrate, and drop-casting a flexible substrate material solution on the substrate so as to form a flexible substrate attached with the plurality of conductors. The method may further include removing, from the substrate, the flexible substrate attached with the plurality of conductors. The method may further include cleaning the substrate prior to applying the conductive solution to the substrate.

In one example, the method may further include masking (e.g., using a patterned photoresistive mask) part of the substrate prior to spray coating the conductive solution on the substrate. In another example, the method may further include masking (e.g., using a patterned photoresistive mask) the plurality of conductors formed on the substrate; and performing a photolithography operation on the masked conductor layer so as to remove some of the conductors.

The conductive solution may include silver nanowire solution and the conductor layer may include a silver nanowire layer.

Attaching the photodetector units may include: masking (e.g., using a patterned photoresistive mask) part of the flexible substrate attached with the plurality of conductors, and spray coating a ZnO—MoS₂ solution onto the masked flexible substrate to attach a plurality of ZnO—MoS₂ photodetector units to the flexible substrate attached with the plurality of conductors. Preferably, the ZnO—MoS₂ solution comprises 3-6 wt. % of ZnO nanoparticles. The spray coated ZnO—MoS₂ solution may be heated to form the plurality of ZnO—MoS₂ photodetector units. The ZnO—MoS₂ photodetector units are electrically connected with the plurality of conductors when formed.

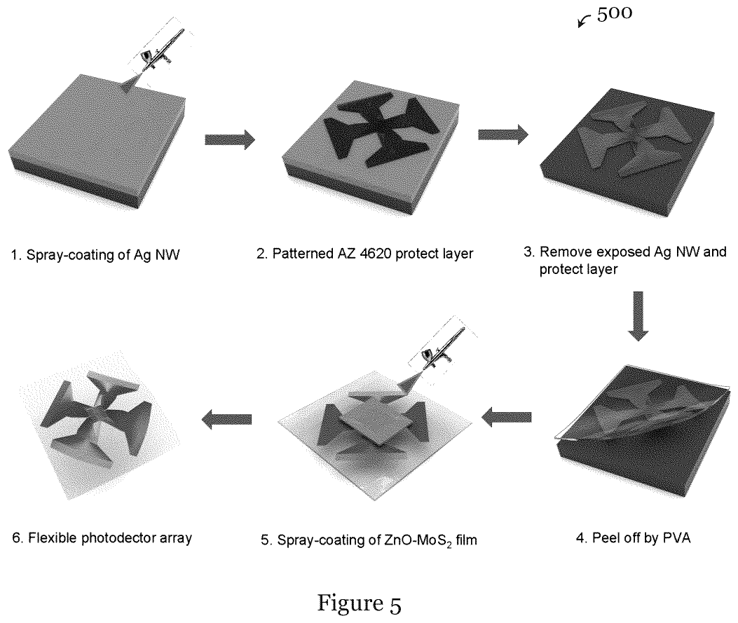

FIG. 5 shows a method 500 for making a photodetector (such as the photodetector 100 of FIG. 1) in one embodiment of the invention. The method 500 involves spray-coating silver nanowires solution on a glass substrate to form a silver nanowires layer. Then, a patterned protect layer (photoresist) is applied on the silver nanowires layer. The assembly is then subjected to photolithography, and afterwards, the protect layer and the exposed part of the silver nanowires layer are removed. A PVA solution is drop casted on the resulting assembly to form a PVA film attached with the silver nanowires. The PVA film attached with the silver nanowires is then peeled off from the glass substrate. Then, a patterned protect layer (photoresist) is applied on the PVA film, and a ZnO—MoS₂ solution is spray-coated onto the masked PVA film. Subsequently, the patterned protect layer (photoresist) is removed, and the ZnO—MoS₂ photodetector array is attached to the PVA film.

In one example, an ultraviolet photodetector based on ZnO nanoparticle-MoS₂ monolayer was made based on the following. Glass substrates were cleaned in an ultrasonic bath with detergent water, acetone, deionized water, and isopropyl alcohol for 15 minutes each sequentially. Then, the substrate was treated with energetic oxygen plasma (45 W) in a Harrick zlasma cleaner for 5 minutes to create a hydrophilic surface. Assisted by a metal mask with designed pattern, silver nanowires solution was sprayed onto glass substrate with a discharge speed of 40 mL/30 s by an IWATA HP-CP spray gun (0.3 mm) connected with a portable air pump at an air pressure of 15 psi. Then two coplanar electrodes with 100 μm width were formed. Next, 10 wt. % aqueous solution of PVA was drop-casted onto the glass substrate. After drying naturally at room-temperature, the PVA film embedded with coplanar electrodes was peeled off from the substrate, resulting in stable and smooth conductive surface. The ZnO nanoparticle dispersion was mixed with MoS₂ dispersion directly with concentrations of 3-6 wt. % and stirred for 24 hrs. This concentration was defined by weight of ZnO nanoparticles divided by whole solution weight. The mixed solution was well-dispersed by ultrasonication for 5 minutes before casting. Then using a metal mask, the mixed solution was sprayed onto the PVA film by a spray gun with at an air pressure of 25 psi generated by air pump for ˜12 s and baked in 80° C. drying oven for 5 minutes to form patterned thin-film ultraviolet photodetector. For the device with 6 wt. % ZnO nanoparticles with a thicker film, the spray duration is ˜30 s.

In one example, an optoelectronic system 200 with a photodetector 100 having an optically-transparent photodetector array was made based on the following. The method began with spray-coating silver nanowires solution onto whole pre-cleaned 7.5×7.5 cm² glass substrate as the same spray-coating parameters in the above example. After deposition of silver nanowires film, photolithography and developing defined a layer of patterned hard photoresist (PR, AZ 4620, AZ Electronic Materials) on the surface of silver nanowires film. Then a sash style paint brush was used to remove the exposed Silver nanowires, followed by immersion of the substrate in Acetone for 10 minutes to remove the photoresist, then desired pattern of silver nanowires film was developed. The thinnest path and minimum separation of the silver nanowires circuit was 30 μm. Next, 10 wt. % aqueous solution of PVA was drop-casted onto the patterned silver nanowires film. After drying naturally at room-temperature, the PVA film embedded with patterned silver nanowires circuit was peeled off from the substrate. Then a metal mask with designed pattern of square array was used to spray coating 4 wt. % ZnO—MoS₂ solution onto PVA film as the same spray-coating parameters described above. Then surplus part of the PVA film was cut off by scissors, resulted in a generally cross-shape. Finally, the free-standing soft photodetector array was mounted on the designed PMMA dome, anchored with custom-made PCB by PDMS pad between the PCB and PMMA substrate. Aligned and tighten contact between pads on PCB and flexible circuit ensured stable connection for image acquisition (FIGS. 6A-6B).

Exemplary materials used in the above method of making examples include Molybdenum disulfide powder (MoS₂, Innochem), Copper foil (Shenzhen Kejing Star Technology Company), lithium foil (DodoChem), 1 M LiPF₆ dissolved in a mixture of ethyl carbonate (EC), dimethyl carbonate (DMC) and ethyl methyl carbonate (EMC) at a volume ratio of 1:1:1 (DodoChem), Polypropylene (pp) film (Celgard 2300, North Carolina, USA), Poly(vinylidene fluoride) (PVDF, fluorochem), N-methylpyrrolidone (NMP, J&K Scientific Ltd), Acetone (Macklin), Deionized water was purified using Milli-Q System, Zinc Oxide nanoparticles (Sigma-Aldrich, ≤40 nm avg. part. size, 20 wt. % in H₂O), Silver nanowire (XFNano, average length: 20 μm, diameter: 30 nm. 5 mg/mL dispersed in ethanol), Poly (vinyl alcohol) (Sigma, Mw 31000-50000, 98-99% hydrolyzed). In other example, other materials or brands can be used.

In one example the optoelectronic system 200 was assembled based on the following. First, the soft photodetector 100 was attached to the PCB according to the designed loci, and the connection silver nanowires pads embedded in the substrate were aligned and connected with the protuberant pads on the PCB. Then the photodetector array of the photodetector 100 were placed right in the center of the skeletonized circular hole on the PCB. Four soft PDMS anchor pads (˜0.8 mm thick, 4 cm long, 5 mm wide) were attached on the positions of the protuberant pads on the PCB. Then the PMMA hemispherical dome then tightly fits the soft photodetector array from below to minimize or gaps between the substrate and the PCB. Finally, fasteners such as screws are nuts are run through the upper PCB and bottom PMMA substrate were tightened to stabilize the system.

FIGS. 6A and 6B show the width of the conductive paths of the silver nanowires, which ranges from 30 μm to 250 μm. The silver nanowires serve as interconnects and connection pads to the signal processor or data acquisition system.

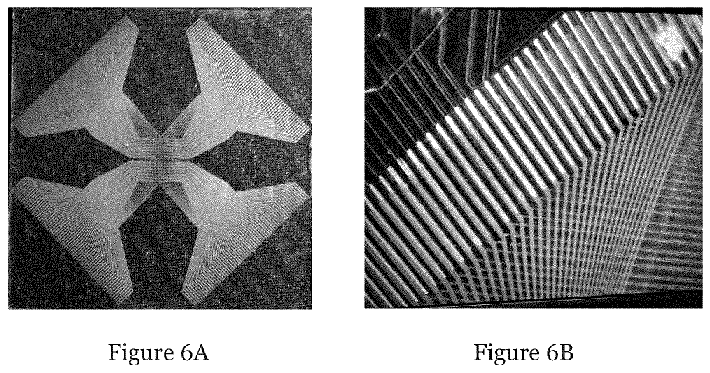

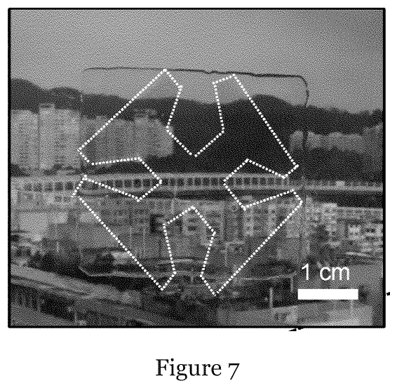

In some embodiments all the functional materials used in the photodetector are optically-transparent, and as a result the device can be substantially invisible when attached on the surface of other objects. As shown in FIG. 7, the corresponding photodetector attached to a window exhibits remarkable transparency.

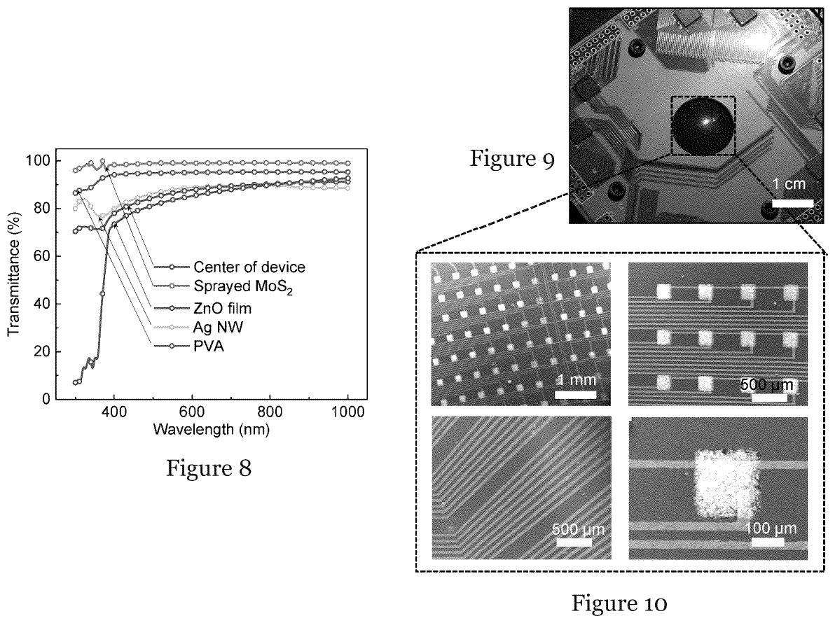

FIG. 8 shows optical transmittance of different layers in the photodetector 100. As shown in FIG. 8, the individual layers of MoS₂, ZnO, silver nanowires and PVA all exhibit transparency of at least 85% between 450 nm and 900 nm. As a result, the entire device with all these functional layers assembled yields an average transmittance of ˜85% in the visible light range. The high optical transparency allows the photodetector array to respond to the UV light from both front and back sides without substantially causing visible light intensity weakening.

FIG. 9 shows the top view of part of the optoelectronic system 200, where the soft photodetector array is attached on the curved PMMA surface, and the PCB connects to a signal processor (e.g., semiconductor device parameter analyzer) for data acquisition and/or processing. FIG. 10 shows enlarged views of the transparent photodetector array in this example. The photodetector array includes 256 (16×16) independent photodetector units within 1 cm² area and flexible circuit based on silver nanowires. The side length of each photodetector unit is 200 μm and the spacing between adjacent photodetector units is 670 μm. The island structure of the photodetector array and ultra-thin feature (450 nm) of each photodetector unit ensure good mechanical properties. The silver nanowires connection pads are aligned and connected with the protuberant pads on the PCB for electrical signal measurement.

The optoelectronic performance of the photodetector units is an important factor affecting operation of the photodetector 100 or the optoelectronic system 200. Considering that single-layer metallic 1T MoS₂ (trigonal antiprismatic configuration) with natural flexibility can be used to enhance the separation/transport of photogenerated carriers, in one embodiment of the invention, MoS₂ is composited with ZnO nanoparticles to improve the optoelectronic performance.

The following includes disclosure relates to the experimental testing and application of the photodetector 100 and/or the optoelectronic system 200.

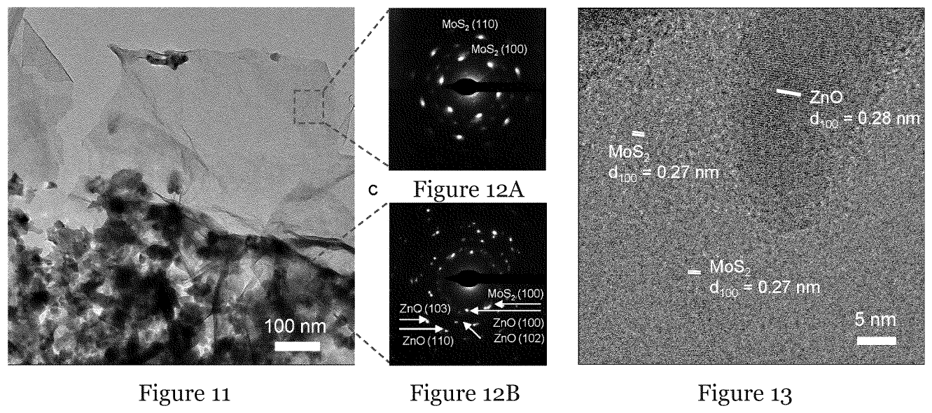

FIGS. 11-15B shows the morphology and structure characterization of ZnO nanoparticles-MoS₂ monolayer composites.

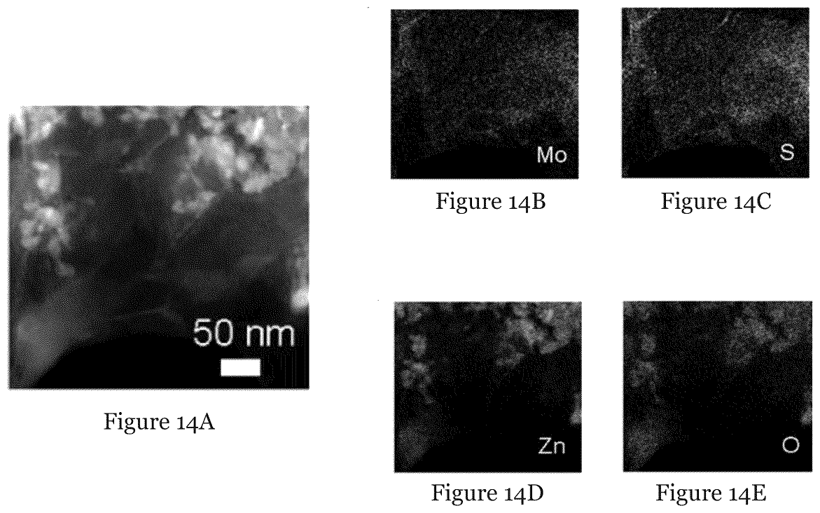

As shown in the TEM images of Figure ii, ZnO nanoparticles cover the smooth surface of the MoS₂ nanosheets. In FIGS. 12A-12B, the corresponding diffraction pattern represent the (100) and (110) planes for MoS₂, and the (100), (002), (102), (103) and (110) planes of ZnO are shown. FIG. 13 shows the HR-TEM image of the ZnO—MoS₂ composites, where the measured lattice space of 0.27 nm assigned to the (100) plane of MoS₂, 0.28 nm and 0.248 nm attributed to the (100) and (101) plane of ZnO are in well agreement with the theoretical values (JCPDS no 06-0097, JCPDS no 36-1451). The HAADF-STEM images in FIGS. 14A-14E demonstrate the existing of Mo, S, Zn, 0 elements in the sample.

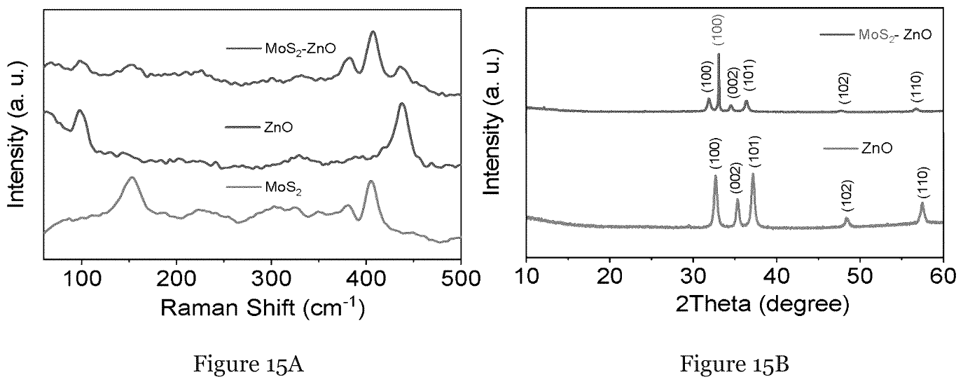

In the Raman spectrum of FIG. 15A, exfoliated MoS₂ nanosheets has J1 J2 J3 peaks at 153 cm⁻¹, 233 cm⁻¹ and 325 cm⁻¹, 1T MoS₂ prepared, and two shoulder peaks at 380 cm⁻¹ and 405 cm⁻¹ are attributing to the E¹_{2g} (in-plane mode, the opposite vibration of two S atoms with respect to the Mo atom) and A_{1g} (out-of-plane vibration of only S atoms in opposite directions) of MoS₂ structure. Two dominated peaks at 98 cm⁻¹ and 438 cm⁻¹ are observed in Raman spectrum of ZnO, ascribing to E₂ (low) and E₂ (high) mode of ZnO structure, indicating that the sample has good crystal quality. After hybridizing the MoS₂ and ZnO structure, ZnO—MoS₂ composite keep their respective Raman peaks.

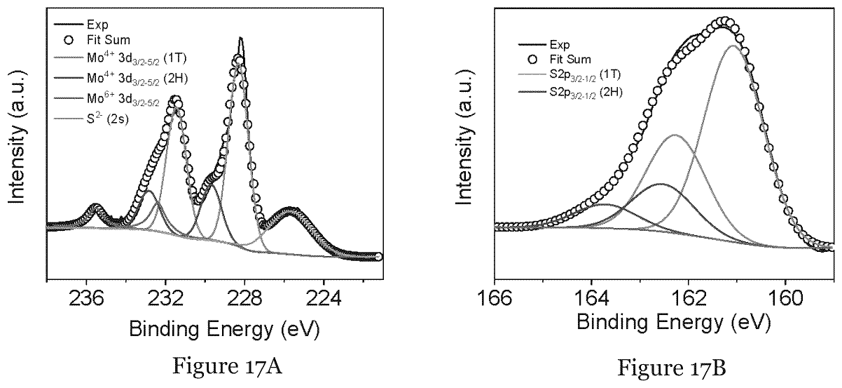

As shown in FIGS. 17A-B, both the Mo3d and S2p spectrum of exfoliated MoS₂ nanosheets proving the dominated 1T MoS₂ structure fabricated, in agreement with Raman result, which is metallic phase with good conductivity.

In the XRD spectrum of FIG. 15B, featured peaks corresponding to (100), (002), (101), (102) and (110) crystal planes of hexagonal ZnO structure (JCPDS no 36-1451) are clearly seen. For ZnO—MoS₂ sample, apart from above-mentioned peaks, the peak assigned to (100) plane of MoS₂ (JCPDS no 06-0097) is also noted as well, which is consistent with TEM result. These results confirm the high-quality crystallization of the ZnO—MoS₂ structure, which are beneficial to reduce charge traps and facilitate charge transport under illumination, thus advantageous for photo (light) response.

Single-layer MoS₂ nanosheets were synthesized an electrochemical lithium intercalation and exfoliation method. Briefly, Bulk MoS₂ was coated on the copper surface and assembled in lithium-ion battery used as cathodes, lithium foil as anode and dissolved LiPF₆ as electrolyte. Lithium was driven into the interlayer of the bulk MoS₂ structure via performing galvanostatic discharge process, after finishing the intercalation via controlling the discharging condition, the lithiated sample (LiₓMoS₂) was taken out from the battery and sonicated in DI water, then opaque suspensions were obtained, which was washed and purified for characterization and composited with ZnO.

The room temperature processing route enables high yield of the single-layer nanosheets as well as large-scale production.

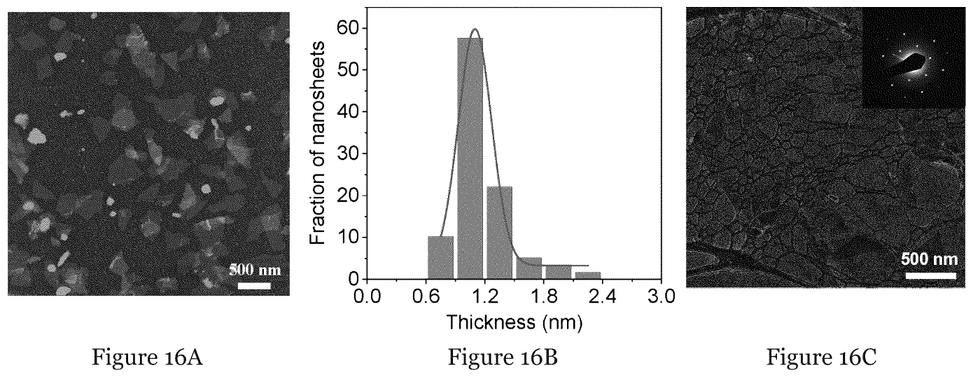

AFM image and thickness statistical results of the exfoliated MoS₂ nanosheets shown that 90% nanosheets are single-layered (FIG. 16A-16C), which guarantees good charge carrier transportation properties. Both the AFM and TEM images display the nanosheet morphology with lateral size of hundreds of nanometers, diffraction pattern shown the inner six spots assigned to the (100) plane and outer six spots attributed to the (110) plane of the MoS₂ structure, indicating good crystallinity of the exfoliated MoS₂ nanosheets.

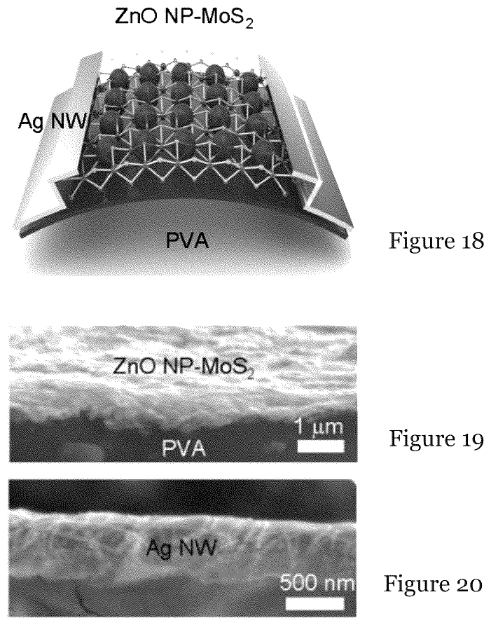

FIG. 18 shows a schematic of a single photodetector unit based on ZnO nanoparticles-MoS₂ monolayer composite. FIGS. 19 and 20 show the sectional view of the unit. As UV light illuminates on the photodetector unit of the array, the illuminated photodetector unit (sensing pixel) in the photodetector would produce photocurrent. Thus, the photo-responsivity and current on/off ratio of the photodetector units are two parameters that greatly influence the performance of the photodetector.

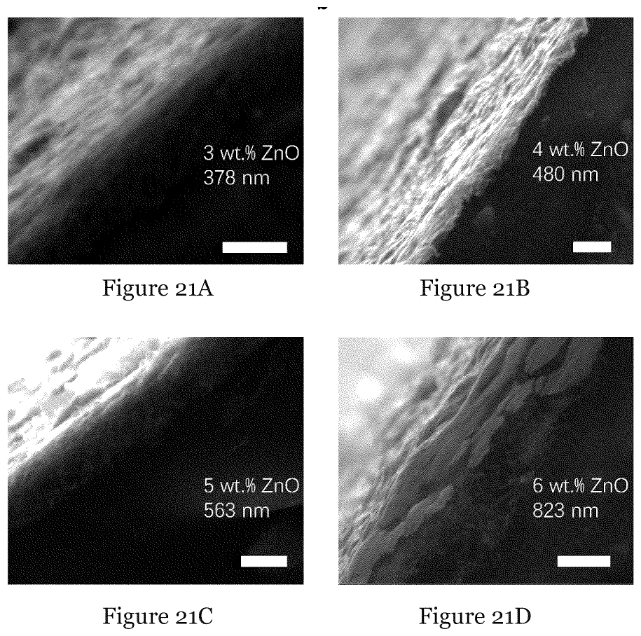

To determine the optimized performance of the photodetector unit, the device performance of the ZnO nanoparticles-MoS₂ photodetector units with different concentration of ZnO nanoparticles was investigated. The film thickness is controlled by the variation of ZnO nanoparticles concentration, and thus higher concentration results in thicker film, as shown in FIGS. 21A-21D.

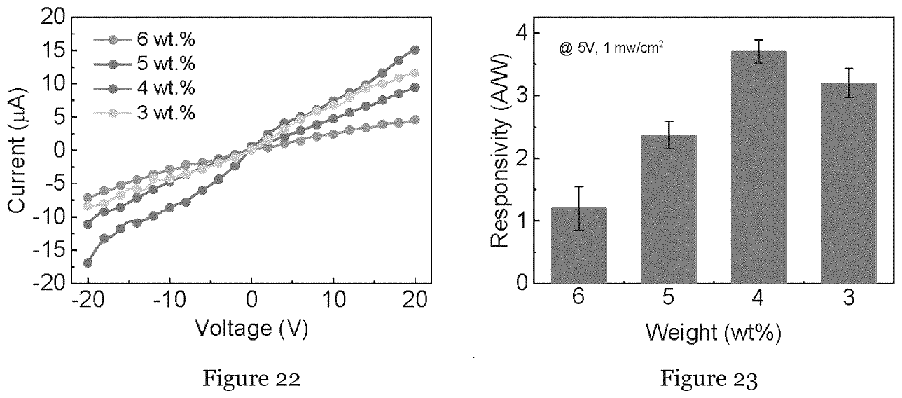

As shown in FIG. 22-23, the device with 3 wt. % ZnO nanoparticles exhibits a photo responsivity of 3.2 A/W at a bias of 5 V. When the concentration of ZnO nanoparticles increases to 4 wt. %, the photo responsivity increases to 3.7 A/W at a bias of 5V. However, further increasing ZnO nanoparticles concentration to 5 wt. % and 6 wt. % causes a decrease in photo responsivity, 2.37 A/W and 1.2 A/W respectively.

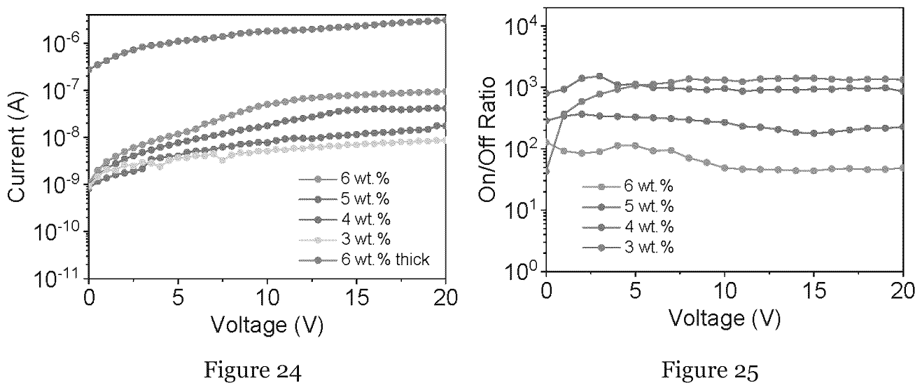

FIG. 24 shows that the dark current of the device increases gradually from 3.2 nA to 10.8 nA with increasing concentration of ZnO nanoparticles from 3 wt. % to 6 wt. %. In addition, the film thickness could be further increased by increasing spray duration. Extension of the spray duration by 3 times with all the other parameters unchanged leads to a significant deterioration of dark current, where the device with 6 wt. % ZnO nanoparticles plus 3 times longer spray duration shows a dark current of 1.01 μA, which is 3 orders of magnitudes higher that of the normal device with 6 wt. % ZnO nanoparticles. Such increase of dark current could be attributed to denser film that results in larger number of ZnO neighboring particles. Meanwhile, absorption of oxygen could be limited deep in the dense film and lead to ZnO domains that are less electron-depleted, thus higher film conductivity. Moreover, such ZnO domains are also fewer light sensitive which decrease the number of photo-generated carries leading to decrease of photocurrent. So, film thickness affects the device performance.

The device formed with an optimized concentration of 4 wt. % ZnO (of the ZnO—MoS₂ composite) show the highest on/off ratio over 103 under 5 V (FIG. 25), which is much higher than the conventional silicon photodetector.

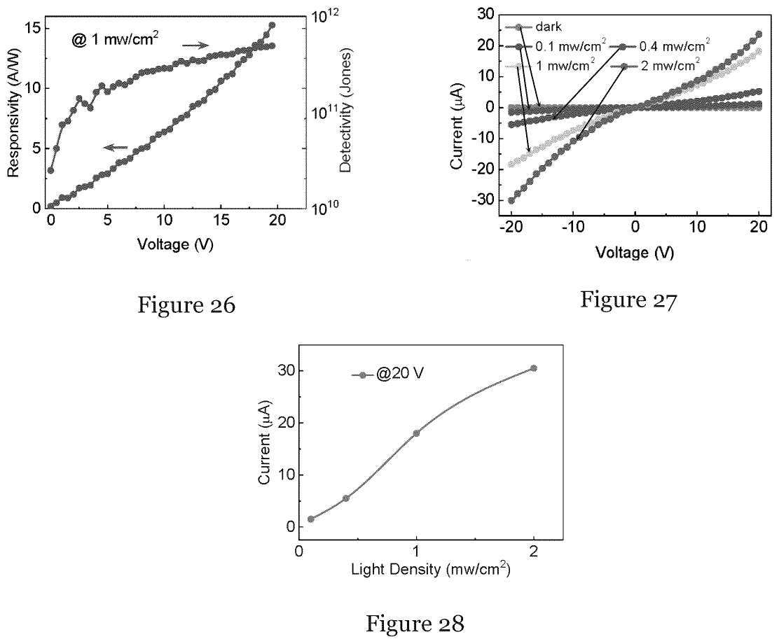

The detailed performance of the device with 4 wt. % ZnO nanoparticles (of the ZnO—MoS₂ composite) as the optimized parameter are further investigated. As shown in FIG. 26, the device formed with 4 wt. % ZnO nanoparticles (of the ZnO—MoS₂ composite) show a high detectivity over 10¹¹ Jones and a high responsivity of 15.2 A/W under a bias of 20 V.

FIGS. 27-28 show the photocurrent of the vice with 4 wt. % ZnO nanoparticles (of the ZnO—MoS₂ composite) under different light intensities from 0.1 mw/cm² to 2 mw/cm². Under the illumination of 365 nm light, the devices can generate an approximately linear response to different light intensities, confirming the sensitive response of the devices.

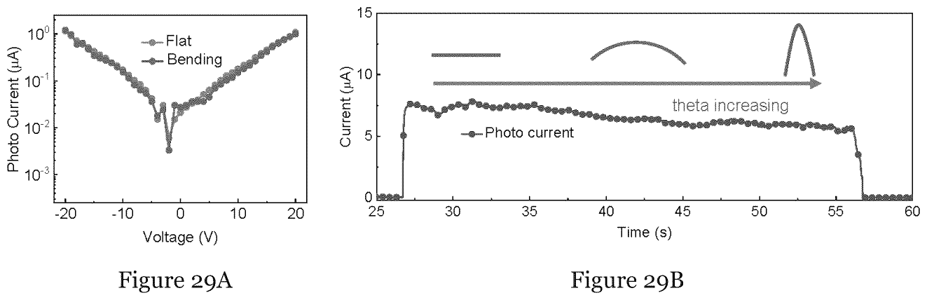

The photocurrents of the photodetector units under bending condition were measured. The results are shown in FIGS. 29A-B. Owing to intrinsic flexibility of the low-dimensional nanomaterials, the device shows stable light-response under various bending conditions. Such stable mechanical property ensures the function of the photodetector array even when mounted on a curvy surface.

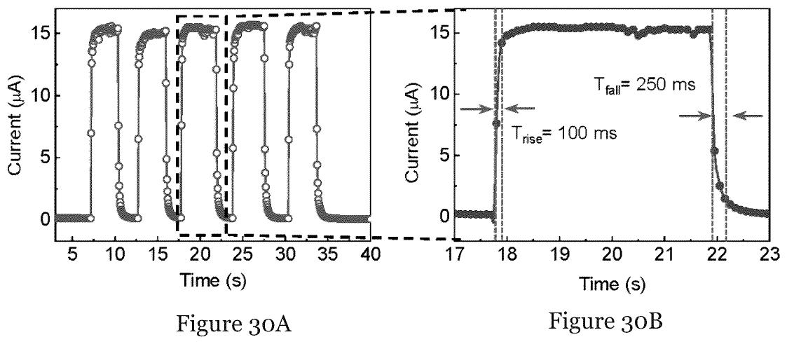

FIGS. 30A-30B show the dynamic photo response measurements under 1 mw/cm² illumination. The device shows fast and repeatable photo response, indicating good stability and reproducibility under multiple cycles of illumination. The response and recovery time of the device of 4 wt. % ZnO nanoparticle-MoS₂ are 100 ms and 250 ms, respectively, which are much faster than pure ZnO nanoparticles photodetector units. The fast response time in the ZnO nanoparticle-MoS₂ photodetector units associates with the unique carrier transport behaviors between ZnO nanoparticles and MoS₂ monolayers. To investigate the charge transfer and separation efficiency in ZnO—MoS₂ composite, photoluminescence spectrum (PL) and time-resolved photoluminescence spectrum (TRPL) spectrum were measured.

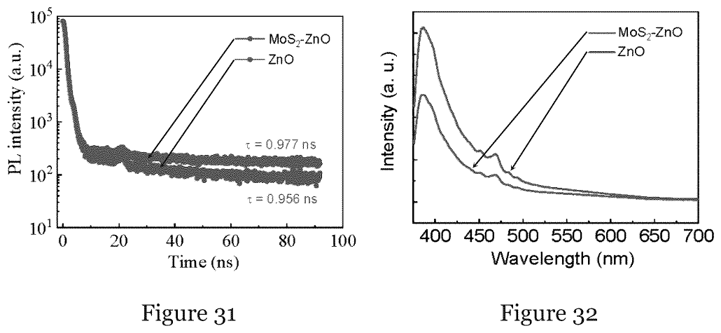

FIG. 31 shows the TRPL result of the ZnO and ZnO—MoS₂ composites under excitation at 365 nm. The TRPL decay spectrum curves were fitted by an exponential decay kinetics function expressed as the following equation.

$$I ( t ) = {A}_{1} \times {e}^{- \frac{t}{{τ}_{1}}} + {A}_{2} \times {e}^{- \frac{t}{{τ}_{2}}} + {A}_{3} \times {e}^{- \frac{t}{{τ}_{3}}}$$

Meanwhile, the average emission lifetime (τ), reflecting the overall emission decay behavior, was calculated through below equation:

$$τ = \frac{{A}_{1} {τ}_{1}^{2} + {A}_{2} {τ}_{2}^{2} + {A}_{3} {τ}_{3}^{2}}{{A}_{1} {τ}_{1} + {A}_{2} {τ}_{2} + {A}_{3} {τ}_{3}}$$

The charge carrier lifetime of MoS₂—ZnO (0.977 ns) is higher than that of the pure ZnO (0.956 ns), indicating that ultrathin 1T-phase MoS₂ nanosheets enhance the separation efficiency of electrons and holes. PL spectrum presented in FIG. 32 shows that an emission peak at 386 nm appears after exciting at 365 nm. It is obvious that the peak intensity of the composite quenched a lot after loading MoS₂, ascribing to the fast electron transfer from ZnO to MoS₂, which can suppress the recombination of electrons and holes, consistent with the TRPL result. UV-Visual absorption spectrum was used to investigate the bandgap of ZnO and MoS₂, which can be calculated through the following equation:

$${( α hv )}^{\frac{1}{n}} = A ( hv - {E}_{g} )$$

where α is absorption coefficient, A is a constant, h is the Planck's constant, ν is the frequency of the incident light, E_{g} is bandgap energy, and n is equal to ½ for ZnO and 1T MoS₂ (direct transition).

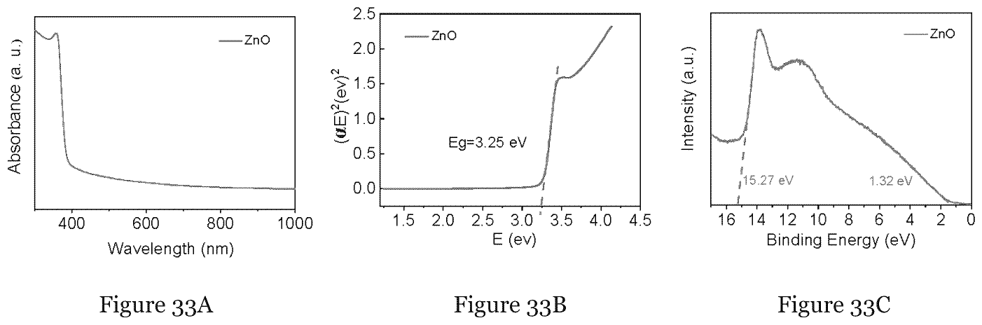

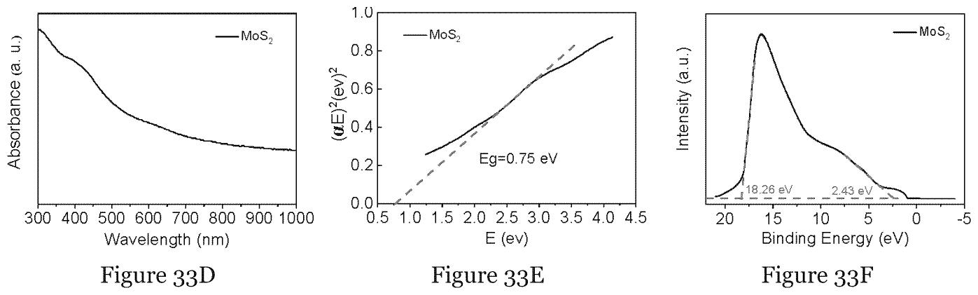

FIGS. 33A-33F show the UV-Visual absorption spectrum and corresponding Kubelka-Munk transformed reflectance spectra of ZnO and MoS₂, and the bandgap of ZnO and MoS₂ is calculated to be 3.25 eV and 0.75 eV. The work function of the ZnO nanoparticle and 1T MoS₂ nanosheets are measured by ultraviolet photoelectron spectroscopy spectrum (UPS), which is calculated as 5.9 eV and 3.0 eV (FIGS. 33C and 33F).

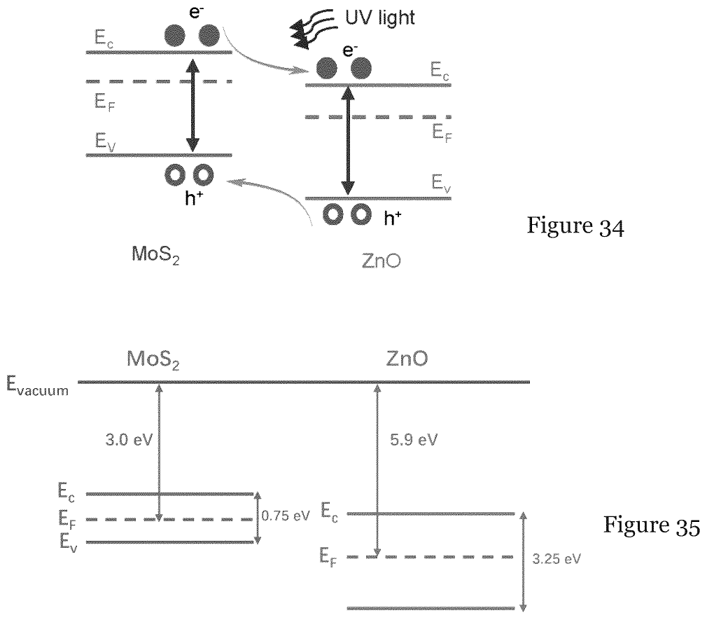

FIGS. 34 and 35 show the energy band diagrams for the photodetector unit of the photodetector 100. The difference in work functions of n-ZnO nanoparticles and p-MoS2 could cause electrons diffusion at the junctions to balance the Fermi level. As a result, p-n heterojunctions are formed between n-ZnO nanoparticles and the p-MoS₂ monolayer. When UV light illuminating the device, photo-generated carries can be quickly separated by the built-in electrical field and transfer to electrodes under voltage bias, and thus resulting in an enhanced response speed. Such rapid light response can easily meet the high-speed data acquisition requirements of electronic eye systems.

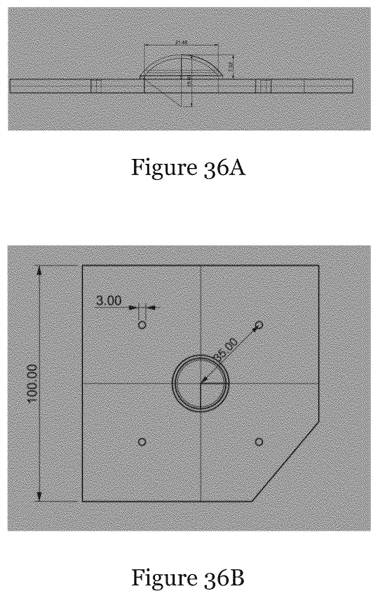

After testing the performance of photodetector units, the imaging characteristics of the transparent photodetector array mounted on the curvy surface we investigated. In this embodiment the fabricated free-standing soft photodetector 100, in particular its photodetector array, is mounted on the surface of the customized PMMA dome, anchored with PCB by PDMS pad between the PCB and PMMA support structure (substrate). FIGS. 36A-36B show the construction of the PMMA support structure. As mentioned with reference to FIG. 6A-6B, aligned and tighten contact between pads on PCB and flexible circuit ensure stable connections for data acquisition.

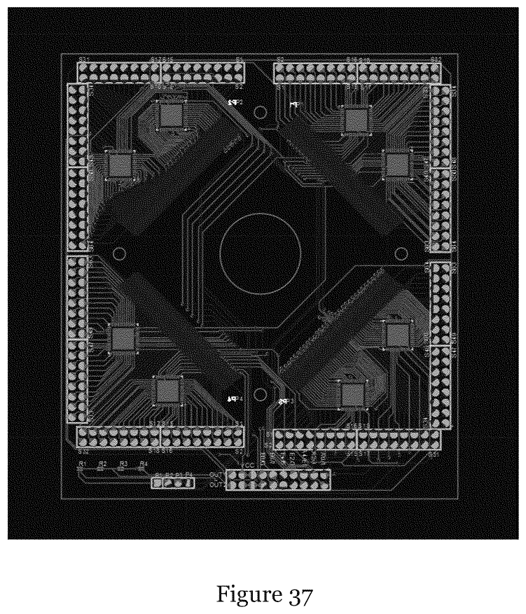

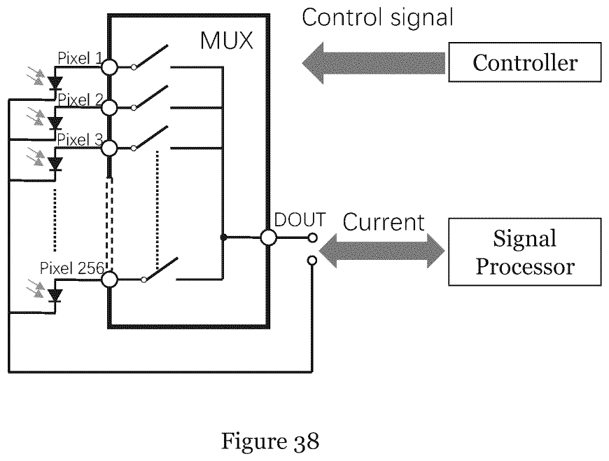

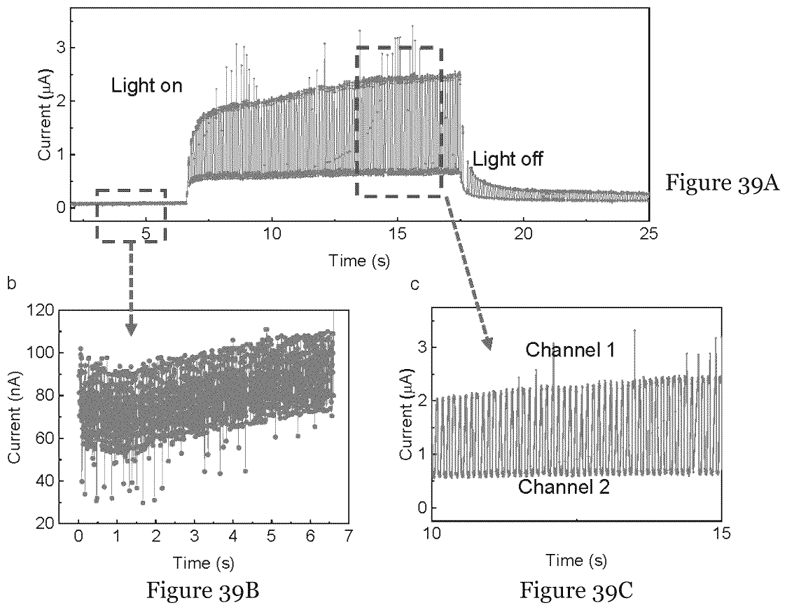

FIGS. 37-39C present the PCB layouts and mechanism of signal processing and/or data acquisition for the optoelectronic system 200. In this example the control circuit includes a controller or control board (Arduino nano) and eight pieces of 32-channel multiplexer. As shown in FIG. 38, the controller controls the multiplexers to turn on the selected channel and close the other channels. A signal processor in the form of a semiconductor device parameter analyzer is connected to the positive and negative ends of the conductive channels, and the signal from the corresponding photodetector unit (i.e., pixel) can be measured and collected. The control board automatically sweep the activated channel under of frequency of 1 Hz, and thus the data from all the photodetector units can be collected and traversed to obtain the image.

In general, most biological eyes in nature have simple compound or chambered structures with unique optical imaging properties. The photodetector 100 and system 200 of some embodiments of the invention can mimic either of the two structures as an imaging device.

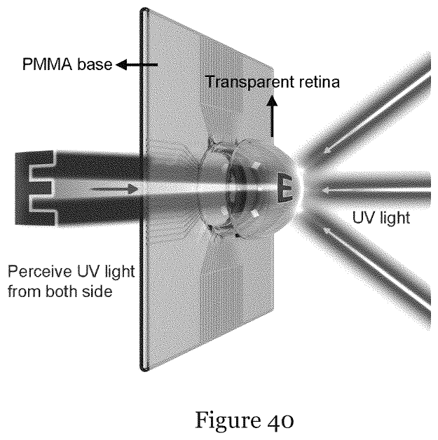

FIG. 40 shows the schematic illustration of the electronic eye imaging system which can be implemented using the photodetector 100 and system 200. The optical transparency of the photodetector (acts as an artificial retina) allows the electronic eye system to perceive light from both front and back sides, and therefore realize two kinds of natural eye prototypes (concave and convex hemisphere) in one device configuration.

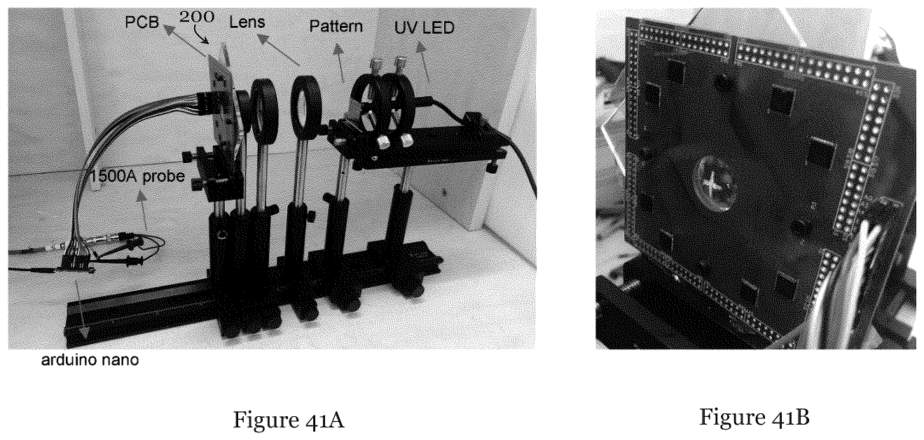

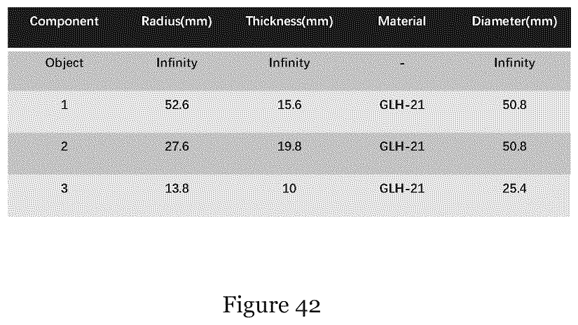

FIGS. 41A-41B show the set-up of the system for mimicking the chambered eye with concave hemisphere, with lighting passes through a simple lens set-up and focuses on the concave side of the photodetector 100 (acts as an artificial retina). The system includes the optoelectronic system 200 and a UV light source, with a pattern shield for patterning the UV light, and a lens arranged between the system 200 and the UV light source (LED). FIG. 42 shows the exemplary lens used in the system of FIGS. 41A-41B.

In one example, for chambered eye prototype, an ultraviolet light-emitting diode blocked by patterned mask provided patterned light, such as cross and letter ‘E’. Through a simple lens setup, the passed light was focused on the concave side of photodetector array. For compound eye prototype, a 365 nm laser illuminated upon the convex side of photodetector from an angle of ˜45°. For both concave and convex prototypes, the current of each photodetector were measured by Keysight B1500A semiconductor device parameter analyzer. The scanning circuit was composed of an Arduino nano and eight 32-channel multiplexers. Keysight B1500A probes were connected to the channels, and the corresponding sensors could be measured, so that Arduino nano automatically switched the activated channel, all the sensor of the device could be traversed to obtain the image. Then the normalized signal was extracted from the data and reconstructed by the interpolation function of MATLAB.

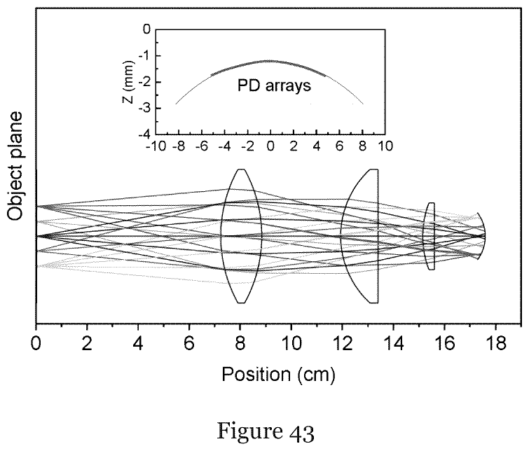

FIG. 43 presents the simulated ray trace of the lens set-up. The hemisphere focal plane is simulated as a curvy surface with a radius of 15 mm which is well matched with the curvature of the soft photodetector array (inset). Controlled by the control circuit with the Arduino nano controller, the photocurrent of each photodetector can be collected and optimized, and then for image reconstruction. The values of the photocurrent in the corresponding sensing pixels are then converted into greyscale values and enumerated in a 16×16 matrix. Specifically, the greyscale values between 0 and 1 are calculated by the equation as followed

$$Grey = \frac{{I}_{light} - {I}_{dark}}{{I}_{full} - {I}_{dark}}$$

where Grey is the greyscale value, I_{light}, I_{full} and I_{dark} are the recorded current values of the devices under specific illumination, full light illumination and dark conditions. Then, the pixelated image was optimized by interpolation, e.g., applying the interpolation function of MATLAB.

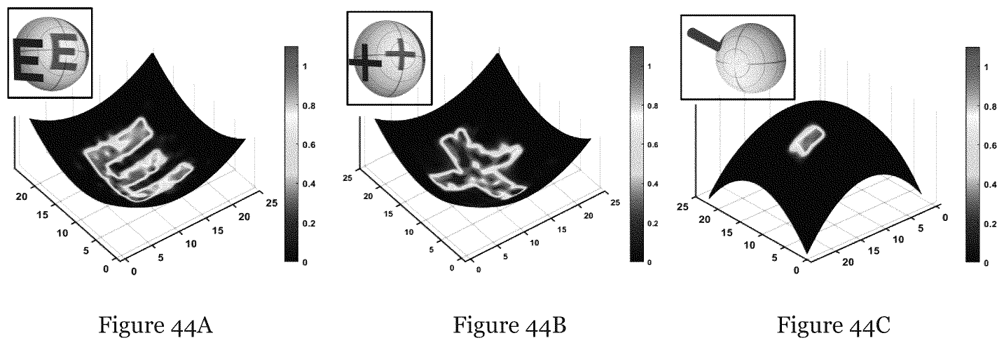

FIG. 44A-44B illustrates the imaging capabilities of the electronic eye system (implemented using the setup of FIG. 41A) associated with imaging patterns of a letter ‘E’ (FIG. 44A) and a cross shape (FIG. 44B) on the front side.

Furthermore, without changing device architecture and connection setup, the electronic eye system can also simulate the function of insect compound eyes by imaging from the back side. As shown in FIG. 44C the electronic eye system (implemented using the setup of FIG. 41A) can also capture the light from the concave side by the photodetector array. A 365 nm laser diode was employed to illuminate upon the convex side of photodetector array from an angle of ˜45° and the current of the corresponding photodetector units increases, while the other unilluminated photodetector units remain in their dark states. Moreover, such imaging function can be further optimized or improved to obtain a wide-angle field of view or high motion sensitivity by applying micro-lens on each pixel.

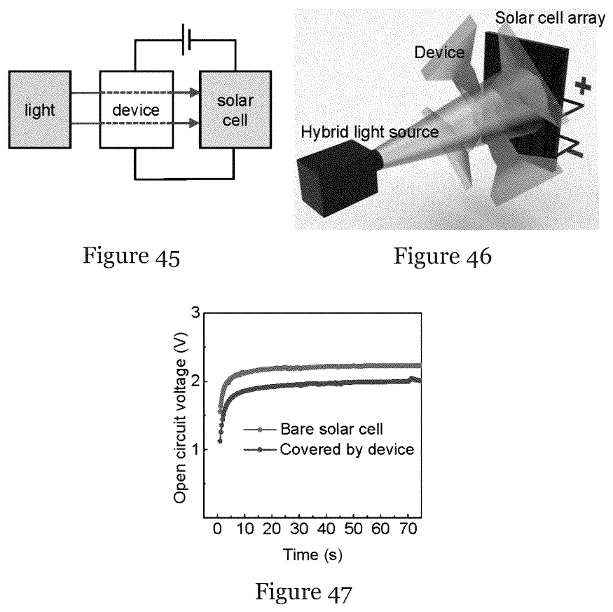

The potential of integrating transparent soft photodetector array with solar cell devices to realize self-powered electronic eye system is also demonstrated. As shown in FIGS. 45-46, the soft photodetector with the photodetector array is attached on the surface of a solar cell or solar cell array. Due to the high optical transparency of the photodetector array, majority of the visible light can penetrate the photodetector and be absorbed by the solar cells. The voltage generated by the solar cells at back of the photodetector only shows slight reduction that of solar cells directly illustrated by light. Thus, the self-powering feature shows the potential for providing voltage bias to the photodetector array without requiring additional wired power supplies (FIG. 47), which can provide a portable electronic eye system.

Some of the above embodiments of the invention have provided a photodetector or an optoelectronic system operable as at least part of a bio-inspired electronic eye system. The system may have an optically-transparent hemispherical acritical retina by full solution/all-solution process, e.g., at room-temperature. Detailed material selection, mechanical design and system level integration proved the good performance of the transparent artificial retina and robust operation behaviors and high throughput processing methods. Such unique transparence allows the retina to perceive light from all directions without weaken of photo-response. Furthermore, two kinds of electronic eye prototypes (concave and convex hemisphere) in one device configuration for dual-sided imaging have been demonstrated. The above embodiments of the invention have also provided a rapid and high-throughput fabrication process for photodetector or optoelectronic system operable as at least part of a bio-inspired electronic eye.

The photodetector, optoelectronic system, or bio-inspired electronic eye in some embodiments of the invention may have various applications in the field of electronics. In one application they provide vison for autonomous technologies such as robotics. Compared to conventional camera system with bulky optical configuration, the photodetector, optoelectronic system, or bio-inspired electronic eye of the invention adopt a relatively simple and relatively small optical geometry and is capable of UV imaging. Such minimized imaging system could be used for image acquisition for mini robotics with requirement of higher system efficiency. In addition, the photodetector, optoelectronic system, or bio-inspired electronic eye in some embodiments can image from both sides, which provides design advantages when the imaging system needs to be steered. In another application they can be used in fault detection in power systems. Corona can be observed by UV imager wherever there is an external discharge, especially for high-voltage power equipment which often produce corona, flashover or arc due to operational faults. The photodetector, optoelectronic system, or bio-inspired electronic eye in some embodiments can record such UV radiation during surface discharge, and then process and analyze it for the purpose of evaluating the condition of the equipment. Prevention and reduction of major losses caused by equipment failures can provide economic benefits.

The photodetector, optoelectronic system, or bio-inspired electronic eye in some embodiments of the invention may be used as or incorporated in an imaging system. Such imaging system may be used in various fields such as unmanned aircraft, autonomous driving, augmented reality and virtual reality. In next-generation imaging system, additional features such as wide field of view, real-time depth sensing, and/or imaging function for invisible light are desired. The photodetector, optoelectronic system, or bio-inspired electronic eye in some embodiments of the invention may be suitable for such purpose. The photodetector, optoelectronic system, or bio-inspired electronic eye in some embodiments of the invention has additional capabilities, such as one or more of: minimized set-up, high optical transparency, facial fabrication process and dual-sided imaging capability. Exemplary potential applications of the invention include, e.g., (1) robotics vison, particularly for humanoid robots that vision system be similar to human in appearance to achieve friendly human-robot interaction; (2) space detection equipment that needs minimized camera system; (3) power system fault detection instruments that detect UV radiation during corona and surface discharge of faulty instruments.

It will also be appreciated that where the methods and systems of the invention are either wholly implemented by computing system or partly implemented by computing systems then any appropriate computing system architecture may be utilized. This will include stand-alone computers, network computers, dedicated or non-dedicated hardware devices. Where the terms “computing system” and “computing device” are used, these terms are intended to include (but not limited to) any appropriate arrangement of computer or information processing hardware capable of implementing the function described.

It will be appreciated by persons skilled in the art that numerous variations and/or modifications may be made to the invention as shown in the specific embodiments to provide other embodiments of the invention. The described embodiments of the invention should therefore be considered in all respects as illustrative, not restrictive.

1. A photodetector for an optoelectronic system, comprising:
a flexible substrate;
a plurality of photodetector units attached to the flexible substrate, each of the plurality of photodetector units being arranged to sense optical radiation and generate a photocurrent signal based on the sensed optical radiation; and
a circuit attached to the flexible substrate, the circuit comprising a plurality of conductors electrically connected with the plurality of photodetector units and being arranged for connecting with a signal processor, the signal processor being arranged to process the photocurrent signals to generate an image associated with the sensed optical radiation.

2. The photodetector of claim 1, wherein each of the plurality of photodetector units comprises a ZnO—MoS2 material.

3. The photodetector of claim 2, wherein each of the plurality of photodetector units comprises a ZnO—MoS2 film.

4. The photodetector of claim 3, wherein the ZnO—MoS2 film comprises ZnO nanoparticles and MoS2 monolayer composite.

5. The photodetector of claim 1, wherein the flexible substrate is optically-transparent to the optical radiation.

6. The photodetector of claim 1, wherein the flexible substrate is in a form of a film made of polyvinyl alcohol (PVA).

7. The photodetector of claim 1, wherein the circuit is optically-transparent to the optical radiation.

8. The photodetector of claim 1, wherein the plurality of conductors comprise nanowires providing connection paths.

9. The photodetector of claim 8, wherein the nanowires are made of silver.

10. The photodetector of claim 9, wherein the circuit comprises a plurality of circuit portions, each having respective patterned silver nanowires, and the plurality of circuit portions are spaced apart.

11. The photodetector of claim 10, wherein each of the plurality of circuit portions includes a relatively narrow inner portion, a relatively wide outer portion, and a middle tapering portion connected between the relatively narrow inner portion and the relatively wide outer portion.

12. An optoelectronic system, comprising:
a support structure having a projection or recess that provides a curved surface;
a photodetector of claim 1, with at least the plurality of photodetector units attached to the curved surface; and
a control circuit electrically connected with the circuit of the photodetector and for connecting the photodetector with a signal processor, the signal processor being arranged to process the photocurrent signals to generate an image associated with the sensed optical radiation.

13. The optoelectronic system of claim 12, wherein the projection or recess is generally dome-shaped.

14. The optoelectronic system of claim 13, wherein the curved surface is a convex surface.

15. The optoelectronic system of claim 13, wherein the curved surface is a concave surface.

16. The optoelectronic system of claim 12, wherein the plurality of photodetector units are attached to the curved surface generally centrally of the curved surface.

17. The optoelectronic system of claim 16, wherein the curved surface is optically-transparent.

18. The optoelectronic system of claim 12, wherein the support structure is made of polymethyl methacrylate (PMMA).

19. The optoelectronic system of claim 12, wherein the control circuit is arranged at least partly on a circuit board, the circuit board comprises an optically-transparent portion at a location corresponding to the curved surface.

20. The optoelectronic system of claim 19, wherein at least part of the photodetector is sandwiched between the circuit board and the support structure, and wherein the circuit board and the support structure are fixed to each other.

21. The optoelectronic system of claim 20, further comprising anchor pads arranged between the circuit board and the support structure for anchoring the photodetector.

22. The optoelectronic system of claim 12, wherein the control circuit comprises:
one or more multiplexers connected with the plurality of photodetector units, each of the one or more multiplexers providing a plurality of channels each having at least one switch and at least one of the plurality of photodetector units; and
a controller operably connected with the one or more multiplexers for controlling operation of the switches of the one or more multiplexers.

23. The optoelectronic system of claim 22, wherein the controller is arranged to:
selectively open and close each of the plurality of switches to selectively disconnect and connect the respective photodetector unit with the signal processor; and
control the switches to sequentially connect each one of the plurality of photodetector units to the signal processor.

24. The optoelectronic system of claim 23, further comprising the signal processor connected with the control circuit;
wherein the signal processor is electrically connected with the plurality of channels to collect the photocurrent signals generated by the plurality of photodetector units; and
wherein the signal processor is arranged to perform image reconstruction based on the photocurrent signals generated by the plurality of photodetector units.

25. The optoelectronic system of claim 24, wherein the signal processor is arranged to perform image reconstruction by:
converting the photocurrent signals to greyscale values; and
generating an image based on the greyscale values.

26. The optoelectronic system of claim 12, further comprising:
an energy source for powering operation of the optoelectronic system, wherein the energy source comprises a photovoltaic cell electrically connected with the photodetector.

27. The optoelectronic system of claim 26, wherein the plurality of photodetector units are arranged in front of the photovoltaic cell.

28. The optoelectronic system of claim 12, further comprising a lens arranged to focus optical radiation onto the plurality of photodetector units.
